(19) United States
(12) Patent Application Publication
(10) Pub. No.: US 2016/0225924 A1
(43) Pub. Date: Aug. 4, 2016

(54) SOLAR CELL WITH SURFACE STAGED TYPE ANTIREFLECTIVE LAYER

(71) Applicant: Kingwave Corporation, Taipei City (TW)

(72) Inventors: Chieh-Hsiung Kuan, Taipei City (TW); Ming-Lun Lee, Taipei City (TW); Wen-Sheng Su, Taipei City (TW)

(21) Appl. No.: 14/808,695

(22) Filed: Jul. 24, 2015

(30) Foreign Application Priority Data
Jan. 30, 2015 (TW) 104103219

(51) Int. Cl. H01L 31/0236; H01L 31/0216

(52) U.S. Cl. CPC H01L 31/02366; H01L 31/02168

(57) ABSTRACT

The present invention provides a solar cell with a surface staged type antireflective layer, comprising a photoelectric conversion layer having a first surface and a second surface opposite from each other and used for receiving incident photons in order to generate charged carriers; a staged type antireflective layer formed on the first surface; the staged type antireflective layer comprising a textured surface structure formed on the first surface via a coarsening method and a plurality of nanostructures formed to protrude from or indent into the textured surface structure; a front-side conductive layer disposed on top the staged type antireflective layer; and a back-side conductive layer disposed underneath the second surface; wherein the s staged type antireflective layer is used for allowing the solar cell to generate an antireflection effect subject to light in a full spectrum range; wherein the full spectrum range is between 300 nm to 1100 nm.

### FIELD OF THE INVENTION

The present invention is related to a solar cell, in particular, to a solar cell with a surface staged type antireflective layer.

### BACKGROUND OF THE INVENTION

With the rapid development of the technology in the recent years, a large amount of energy has been rapidly consumed and the topic on the shortage of energy has become more important in the field. Since solar energy is one of the natural resources that is abundant and readily available to be collected for uses, in addition to that it is not limited by regions with the advantages of pollution free while the technology on the conversion of the sunlight into electricity can also be provided for the operations of various types of devices demand the consumption of the energy, the technology of solar cell has been vigorously developed in various parts of the world. However, currently, one of the main factors associated with the low efficiency of the current solar cells is mostly caused by the amount of light reflected by the solar cell surface. To reduce the reflection, the method of surface roughness and coating of antireflective layer on the solar cells are the most commonly adapted methods in the field. Generally speaking, an anti-reflection coating (ACR) plays a significant role in the efficiency of the solar cell. However, there are still drawbacks associated with the use of the antireflective layer; for example: conventional single layer antireflective layer film thickness is ¼ of the incident wavelength, and such type of film can only generate the effect of reducing the reflection rate within a certain incident wavelength range such that it cannot achieve the effect of lowering the reflection rate in a full spectrum range. Furthermore, if the effect of reducing the reflection rate in a full spectrum range, it must further incorporate other types of antireflective materials or must use the design of multi-layer antireflective layer in order to achieve the reduction of the reflection rate in a full spectrum range, which causes the increase of extra costs. Upon searches, Taiwan Patent Publication No. 1384631 “Black Polycrystalline Silicon Solar Cell and Manufacturing Method Thereof” discloses that an antireflective layer comprising an amorphous silicon nitride layer and a crystalline silicon nitride layer are formed on a polycrystalline silicon solar cell in order to allow the light incident surface of the solar cell sheet to be of a black color and achieve the antireflection for the incident light at the full spectrum range of (400 nm-1100 nm). The aforementioned technology utilizes the coating of an antireflective layer to reduce the reflection rate of the solar cell; however, such method still requires the additional coating of the antireflective layer film, which is relatively more complicated in the manufacturing process and time consuming. In view of the drawbacks of the aforementioned prior art, the inventor of the present invention seeks to provide a method for significantly reducing the reflection rate of the surface cell surface without the need of the use of any additional coating of antireflective layer by providing a solar cell with a surface staged type antireflective layer.

### SUMMARY OF THE INVENTION

An objective of the present invention is to provide a solar cell with a surface staged type antireflective layer such that it requires no additional coating of antireflective layer film on the surface of the solar cell to achieve the effect of reducing the reflection rate to an extreme low level.

Another objective of the present invention is to provide a solar cell with a stage surface type antireflective layer by directly forming a staged type anti-reflective layer on the surface of the solar cell at a low cost in order to achieve the effect of reducing the reflection rate to an extreme low level.

To achieve the aforementioned objectives and others, the present invention provides a solar cell with a surface staged type antireflective layer, comprising: a photoelectric conversion layer having a first surface and a second surface opposite from each other and used for receiving incident photons in order to generate charged carriers; a staged type antireflective layer formed on the first surface; the staged type antireflective layer comprising a textured surface structure formed on the first surface via a coarsening method and a plurality of nanostructures formed to protrude from or indent into the textured surface structure; a front-side conductive layer disposed on top the staged type antireflective layer; and a back-side conductive layer disposed underneath the second surface; wherein the s staged type antireflective layer is used for allowing the solar cell to generate an antireflection effect subject to light in a full spectrum range; wherein the full spectrum range is between 300 nm to 1100 nm.

Wherein the photoelectric conversion layer further comprises a first semiconductor layer disposed adjacent to the first surface and a second semiconductor layer disposed adjacent to the second surface; the first semiconductor layer is an n-type doped layer, and the second semiconductor layer is a p-type doped layer; alternatively, the first semiconductor layer is a p-type doped layer, and the second semiconductor layer is an n-type doped layer.

Wherein the textured surface structure is selected from any one of the shapes of a pyramid array shape, an inverted pyramid array shape, a triangular cross-sectional strip slot shape, a flat-top pyramid array shape, a general dome shape and a ladder cross sectional optical grating shape; and the plurality of nanostructures are selected from any one of the structures of nano-protrusion structures, nano-hole structures and nano-line structures

Wherein the staged type antireflective layer further comprises a crystalline layer and a plurality of nano-column structures; the crystalline layer and the plurality of nano-column structures are sequentially formed on the plurality of nanostructures

In comparison with the known prior art, the solar cell with a surface staged type antireflective layer of the present invention has the following advantages and characteristics: 1. unlike the known technique of coating of antireflective layer film, the present invention requires no additional coating of antireflective layer film on the surface of the solar cell to achieve the effect of reduction of reflection rate to an extremely low level, making the manufacturing process relatively simpler and fast; 2. By directly forming a staged type antireflective layer on the surface of the solar cell, the effect of reducing the reflection rate to an extremely low level is achieved such that the cost is relatively lower while satisfying the demands of the solar cell industry.

### BRIEF DESCRIPTION OF THE DRAWINGS

FIG. 1(a) is an illustration showing a preferred embodiment of a solar cell with a surface staged type antireflective layer;

FIG. 1(b) is an illustration showing another preferred embodiment of a solar cell with a surface staged type antireflective layer;

FIG. 2(a) is an electronic microscopic scanned photograph of a staged type antireflective layer “a” according to the first preferred embodiment of a solar cell with a surface staged type antireflective layer;

FIG. 2(b) is another electronic microscopic scanned photograph of a staged type antireflective layer “b” according to the first preferred embodiment of a solar cell with a surface staged type antireflective layer;

FIG. 2(c) is still another electronic microscopic scanned photograph of a staged type antireflective layer “c” according to the first preferred embodiment of a solar cell with a surface staged type antireflective layer;

FIG. 2(d) is yet another electronic microscopic scanned photograph of a staged type antireflective layer “d” according to the first preferred embodiment of a solar cell with a surface staged type antireflective layer;

FIG. 3 shows a reflection rate curve diagram of the first embodiment of the present invention with various staged type antireflective layers under different wavelengths;

FIG. 4(a) is an electronic microscopic scanned photograph of a staged type antireflective layer “e” according to the second preferred embodiment of a solar cell with a surface staged type antireflective layer;

FIG. 4(b) is another electronic microscopic scanned photograph of a staged type antireflective layer “f” according to the second preferred embodiment of a solar cell with a surface staged type antireflective layer;

FIG. 4(c) is still another electronic microscopic scanned photograph of a staged type antireflective layer “g” according to the second preferred embodiment of a solar cell with a surface staged type antireflective layer;

FIG. 4(d) is yet another electronic microscopic scanned photograph of a staged type antireflective layer “h” according to the second preferred embodiment of a solar cell with a surface staged type antireflective layer;

FIG. 5 shows a reflection rate curve diagram of the second embodiment of the present invention with various types of staged antireflective layers under different wavelengths;

Enclosure 1 is a photograph showing the staged type antireflective layers a, b, c and d according to the first embodiment of the solar cell with a surface staged type antireflective layer of the present invention; and

Enclosure 2 is a photograph showing the staged type antireflective layers e, f, g and h according to the second embodiment of the solar cell with a surface staged type antireflective layer of the present invention.

### DESCRIPTION OF EMBODIMENTS OF THE INVENTION

To understand the objectives, features and effects of the present invention, the following detailed description of the embodiment of the present invention is provided along with the accompanied drawings to further describe the present invention in greater detail as follows.

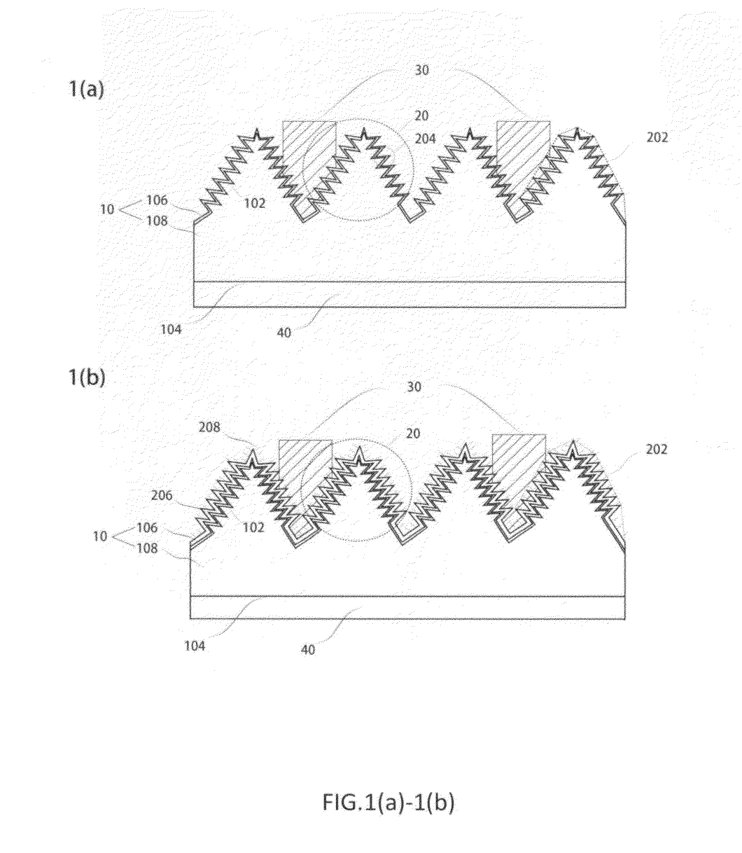

Please refer to FIG. 1(a), showing a preferred embodiment of a solar cell with a surface staged type antireflective layer of the present invention. The solar cell with a surface staged type antireflective layer comprises: a photoelectric conversion layer 10, a staged type antireflective layer 20, a front-side conductive layer 30 and a back-side conductive layer 40; wherein the staged type antireflective layer 20 is used for allowing the solar cell to generate an antireflection effect subject to light in a full spectrum range; and aforementioned the full spectrum range is between 300 nm to 1100 nm

The photoelectric conversion layer 10 includes a first surface 102 and a second surface 104 opposite from each other and used for receiving incident photons in order to generate charged carriers. In addition, the photoelectric conversion layer 10 further comprises a first semiconductor layer 106 disposed adjacent to the first surface 102 and a second semiconductor layer 108 disposed adjacent to the second surface 104. Wherein the first semiconductor layer 106 is an n-type doped layer, and the second semiconductor layer 108 is a p-type doped layer; alternatively, the first semiconductor layer 106 is a p-type doped layer, and the second semiconductor layer 108 is an n-type doped layer. Furthermore, the first semiconductor layer 106 and the second semiconductor 108 can be any one of a Group IV element semiconductor and an alloy thereof, a compound semiconductor of Groups III-V, Groups II-VI and Groups IV-VI elements and an alloy thereof. Nevertheless, in the following embodiments of the present invention, Group IV element semiconductor, such as monocrystalline silicon, multicrystalline silicon or amorphous silicon, is used as an example for illustration.

The staged type antireflective layer 20 is formed on the first surface 102; the staged type antireflective layer 20 comprises a textured surface structure 202 formed on the first surface 102 via a coarsening method and a plurality of nanostructures 204 formed to protrude from or indent into the textured surface structure 202. Wherein the textured surface structure 202 is selected from any one of the shapes of a pyramid array shape, an inverted pyramid array shape, a triangular cross-sectional strip slot shape, a flat-top pyramid array shape, a general dome shape and a ladder cross sectional optical grating shape. In the following embodiment of the present invention, the aforementioned textured surface structure 202 having a pyramid array shape and a general dome shape is used as an example for illustration. Furthermore, the plurality of nanostructures 204 are selected from any one of the structures of nano-protrusion structures, nano-hole structures and nano-line structures, and a method of forming the plurality of nanostructures 204 is selected from any one of the methods of a metal assistance etching (MAE) method, a dry etching method, a wet etching method, a photolithography etching method, a laser engraving method and a combination thereof.

Please also refer to FIG. 1(b), showing another preferred embodiment of the solar cell with a surface staged type antireflective layer of the present invention. The aforementioned the staged type antireflective layer 20 further comprises a crystalline layer 206 and a plurality of nano-column structures 208. The crystalline layer 206 and the plurality of nano-column structures 208 are sequentially formed on the plurality of nanostructures 204. Wherein the crystalline layer 206 is made of a material selected from any one of the materials of a zinc oxide (ZnO) and an aluminum-doped zinc oxide (AZO) and it can be formed by any one of the methods of an atomic layer deposition method, a spin-on coating method, a plasma enhanced chemical vapor deposition (PECVD) method, a molecular beam epitaxy (MBE) method, a pulse laser deposition (PLD) method, a radio frequency magnetron sputter method and a vapor liquid solid (VLS) method. In addition, the plurality of nano-column structures 208 are made of a material of a zinc oxide (ZnO), and they can be formed by any one of the methods of a hydrothermal growth method, a sol-gel method, a metal organic chemical vapor deposition (MOCVD) method, an electrochemical deposition method and a vapor transport deposition (VTD) method. Furthermore, a surface of the staged type antireflective layer 20 is further coated with an antireflective coating layer by using any one of the methods of an atomic layer deposition method, a plasma enhanced chemical vapor deposition (PECVD) method, a molecular beam epitaxy (MBE) method and a vapor liquid solid (VLS) method, and the antireflective coating layer is made of a material selected from any one of the materials of a silicon nitride (Si₃N₄), titanium oxide (TiO₂) and a combination thereof.

The front-side conductive layer 30 is disposed on top the staged type antireflective layer 20 and used for collecting the charged carrier generated by the photoelectric conversion layer 10.

The back-side conductive layer 40 is disposed underneath the second surface 104 and used for collecting the charged carriers generated by the photoelectric conversion layer 10.

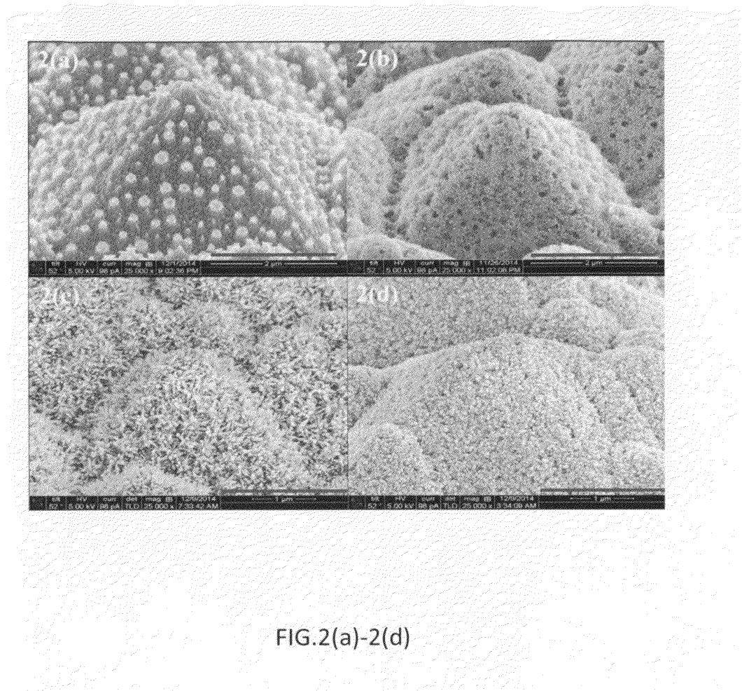

Please refer to FIG. 2, showing electronic microscopic scanned photographs of a first preferred embodiment of the solar cell with a surface staged type antireflective layer of the present invention. In this embodiment, the photoelectric conversion 10 uses the type of monocrystalline silicon as an example for illustration, wherein the first semiconductor layer 106 is an n-type doped layer, and the second semiconductor layer 108 is a p-type doped layer. First, the textured surface structure 202 having a pyramid array shape and is formed by the method of wet etching, followed by coating a metal shielding layer thereon, such as a silver film, with thermal annealing in addition to that the method of dry etching is used to form a plurality of nano-protruding structures 208 on top of the textured surface layer 202; then, the metal shielding layer is removed in order to completely forming an “a” staged type antireflective layer 20, as shown in FIG. 2(a). Following the above, the method of coating with the metal shielding layer, such as a silver film, with thermal annealing in conjunction with the wet etching method or the direct method of metal assistance etching (MAE) can be utilized to form a plurality of nano-hole structures on the textured surface structure 202; then, the metal shielding layer is removed in order to completely forming a “b” staged type antireflective layer 20, as shown in FIG. 2(b). Moreover, by using the “a” and “b” staged type antireflective layers 20 respectively disclosed in FIG. 2(a) and FIG. 2(b) as a base substrate, the method of spin-on coating or radio frequency magnetron sputter can be used to deposit the crystalline layer 206 having the content of aluminum zinc oxide (AZO) thereon; finally, the hydrothermal method can be used to grow a plurality of nano-column structures 208 made of zinc oxide (ZnO) on top of the crystalline layer 206 in order to completely further achieve a “c” staged type antireflective layer 20 and a “d” staged type antireflective layer 20 as shown in FIG. 2(c) and FIG. 2(d) respectively.

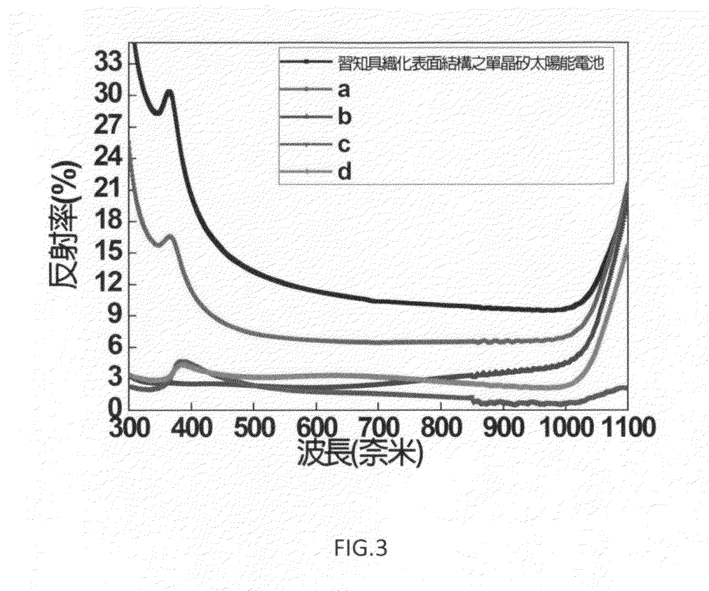

Please refer to FIG. 3, showing a reflection rate curve diagram of the first embodiment of the present invention with various staged type antireflective layers under different wavelengths. As shown in FIG. 3, the black curve is the reflection rate curve of a conventional monocrystalline silicon solar cell having a textured surface structure, and its average reflection rate for the wavelength range between 300 nm and 1100 nm is 13.85%. The red, blue, green and pink curves represent the reflection rate curves of a monocrystalline silicon solar cell with the staged type antireflective layers “a”, “b”, “c” and “d” of the first embodiment of the present invention respectively, and their average reflection rates are 8.79%, 3.63%, 1.81% and 3.47% respectively. It can clearly be understood that the reflection rates of the various staged type antireflective layers proposed according to the first embodiment of the present invention are all clearly lower than that of the conventional textured surface structure; such outcome is mainly due to the fact that the plurality of staged type antireflective layers are able to provide a greater probability of multiple reflections of the sunlight in order to increase the paths for absorbing the sunlight. Such configuration of the present invention also additionally increases the structure of the graded index reflection in order to allow the incident sunlight to be more easily absorbed for utilization; therefore, the antireflection effect of the light is significantly enhanced.

Please refer to Enclosure 1, showing photographs of the staged type antireflective layers “a”, “b”, “c” and “d” of the solar cell with a surface staged type antireflective layer according to the first embodiment of the present invention. The left most of the photographs show a monocrystalline silicon solar cell of a dimension of 2×2 cm² and having a textured surface structure with a pyramid array shape formed thereon. From the photographs, it can be clearly seen that colors and textures of the staged type antireflective layers “a”, “b”, “c” and “d” proposed according to the first embodiment of the present invention are darker than that of the texture surface structure of the conventional solar cell, which means that the incident sunlight of the present invention cannot be reflected easily, and it further demonstrates again that the staged type antireflective layer proposed by the present invention is able to significantly reduce the reflection rate.

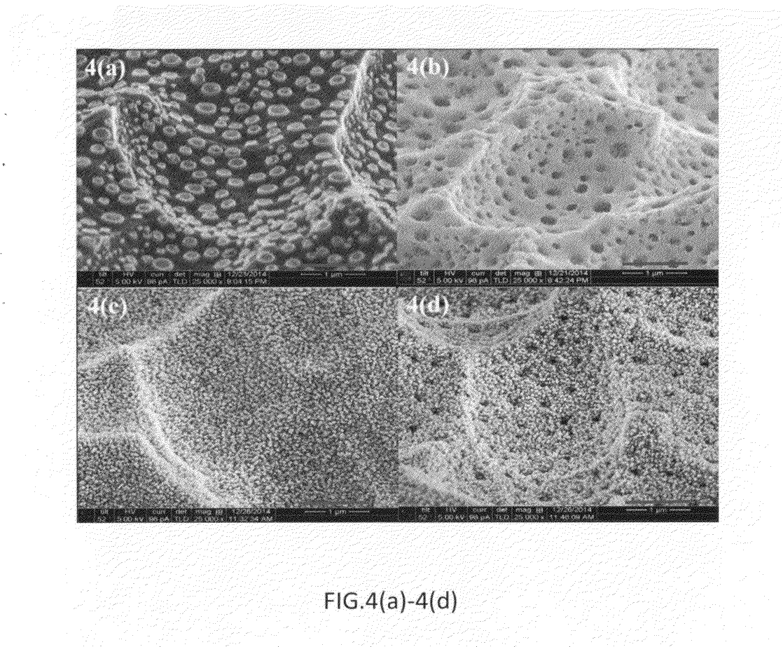

Please refer to FIG. 4, showing electronic microscopic scanned photographs of a second preferred embodiment of the solar cell with a surface staged type antireflective layer of the present invention. In this embodiment, the photoelectric conversion 10 uses the type of multicrystalline silicon as an example for illustration, wherein the first semiconductor layer 106 is an n-type doped layer, and the second semiconductor layer 108 is a p-type doped layer. First, the textured surface structure 202 having a general dome shape and is formed by the method of wet etching, followed by coating a metal shielding layer thereon, such as a silver film, with thermal annealing; then, the metal shielding layer is removed in order to completely forming an “e” staged type antireflective layer 20, as shown in FIG. 4(a). Following the above, the method of coating with the metal shielding layer, such as a silver film, with thermal annealing in conjunction with the wet etching method or the direct method of metal assistance etching (MAE) can be utilized to form a plurality of nano-hole structures on the textured surface structure 202; then, the metal shielding layer is removed in order to completely forming an “f” staged type antireflective layer 20, as shown in FIG. 4(b). Moreover, by using the “e” and “f” staged type antireflective layers 20 respectively disclosed in FIG. 4(a) and FIG. 4(b) as a base substrate, the method of spin-on coating or radio frequency magnetron sputter can be used to deposit the crystalline layer 206 having the content of aluminum zinc oxide (AZO) thereon; finally, the hydrothermal method can be used to grow a plurality of nano-column structures 208 made of zinc oxide (ZnO) on top of the crystalline layer 206 in order to completely further achieve a “g” staged type antireflective layer 20 and a “h” staged type antireflective layer 20 as shown in FIG. 4(c) and FIG. 4(d) respectively.

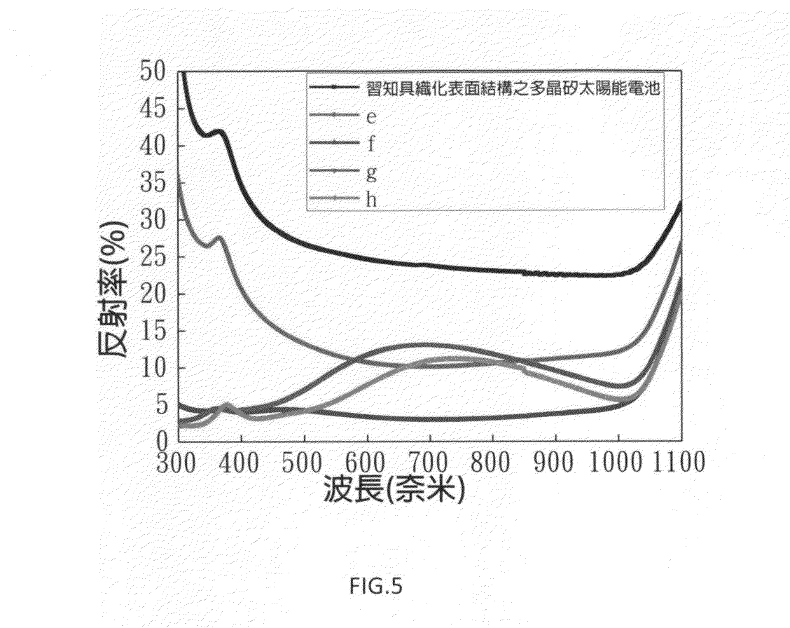

Please refer to FIG. 5, showing a reflection rate curve diagram of the second embodiment of the present invention with various staged type antireflective layers under different wavelengths. As shown in FIG. 5, the black curve is the reflection rate curve of a conventional multicrystalline silicon solar cell having a textured surface structure, and its average reflection rate for the wavelength range between 300 nm and 1100 nm is 27.02%. The red, blue, green and pink curves represent the reflection rate curves of a monocrystalline silicon solar cell with the staged type antireflective layers “e”, “f”, “g” and “h” of the second embodiment of the present invention respectively, and their average reflection rates are 14.39%, 4.47%, 9.42% and 7.43% respectively. It can clearly be understood that the reflection rates of the various staged type antireflective layers 20 proposed according to the second embodiment of the present invention are all clearly lower than that of the conventional textured surface structure; such outcome is mainly due to the fact that the plurality of staged type antireflective layers 20 are able to provide a greater probability of multiple reflections of the sunlight in order to increase the paths for absorbing the sunlight. Such configuration of the present invention also additionally increases the structure of the graded index reflection in order to allow the incident sunlight to be more easily absorbed for utilization; therefore, the antireflection effect of the light is significantly enhanced.

Please refer to Enclosure 2, showing photographs of the staged type antireflective layers “e”, “f”, “g” and “h” of the solar cell with a surface staged type antireflective layer according to the second embodiment of the present invention. The left most of the photographs show a multicrystalline silicon solar cell of a dimension of 2×2 cm² and having a textured surface structure with a pyramid array shape formed thereon. From the photographs, it can be clearly seen that colors and textures of the staged type antireflective layers “e”, “f”, “g” and “h” proposed according to the second embodiment of the present invention are darker than that of the texture surface structure of the conventional solar cell, which means that the incident sunlight of the present invention cannot be reflected easily, and it further demonstrates again that the staged type antireflective layer proposed by the present invention is able to significantly reduce the reflection rate.

In view of the above, the solar cell with a surface staged type antireflective layer disclosed by the present invention is to form a staged type antireflective layer on the surface of the solar cell directly such that it is able to achieve extremely low level of reflection rates with an average reflection rate of 1.81% for a monocrystalline silicon solar cell and an average reflection rate of 4.47% for a multicrystalline solar cell; in addition, the present invention is of lower cost and is readily available for application of mass production such that it meets the demands of the solar cell industry. Moreover, since the comparison between aforementioned plurality of staged type antireflective layers and the known antireflective structures, the staged type antireflective layers of the present invention have a smaller aspect ratio such that for the passivation treatment on the solar cell, they can have more promising outcomes; therefore, greater efficiency can be obtained.

The abovementioned embodiments are provided to illustrate the principles and exemplary methods of manufacturing or formation method of the present invention only. The scope of the present invention shall be defined by the claims recited hereafter, and any modifications or variations to the terms or wordings recited in the claims shall be considered as their relevant equivalence and are within the scope of the present invention. The scope of the present invention shall be determined by the content of the claims recited hereafter.

What is claimed is:

1. A solar cell with a surface staged type antireflective layer, comprising:
a photoelectric conversion layer having a first surface and a second surface opposite from each other and used for receiving incident photons in order to generate charged carriers;
a staged type antireflective layer formed on the first surface; the staged type antireflective layer comprising a textured surface structure formed on the first surface via a coarsening method and a plurality of nanostructures formed to protrude from or indent into the textured surface structure;
a front-side conductive layer disposed on top the staged type antireflective layer and used for collecting the charged carrier generated by the photoelectric conversion layer; and
a back-side conductive layer disposed underneath the second surface and used for collecting the charged carriers generated by the photoelectric conversion layer;
wherein the staged type antireflective layer is used for allowing the solar cell to generate an antireflection effect subject to light in a full spectrum range; wherein the full spectrum range is between 300 nm to 1100 nm.

2. The solar cell with a surface staged type antireflective layer according to claim 1, wherein the photoelectric conversion layer further comprises a first semiconductor layer disposed adjacent to the first surface and a second semiconductor layer disposed adjacent to the second surface.

3. The solar cell with a surface staged type antireflective layer according to claim 2, wherein the first semiconductor layer is an n-type doped layer, and the second semiconductor layer is a p-type doped layer.

4. The solar cell with a surface staged type antireflective layer according to claim 2, wherein the first semiconductor layer is a p-type doped layer, and the second semiconductor layer is an n-type doped layer.

5. The solar cell with a surface staged type antireflective layer according to claim 2, wherein the plurality of semiconductor layers can be any one of a Group IV element semiconductor and an alloy thereof, a compound semiconductor of Groups III-V, Groups II-VI and Groups IV-VI elements and an alloy thereof.

6. The solar cell with a surface staged type antireflective layer according to claim 1, wherein the textured surface structure is selected from any one of the shapes of a pyramid array shape, an inverted pyramid array shape, a triangular cross-sectional strip slot shape, a flat-top pyramid array shape, a general dome shape and a ladder cross sectional optical grating shape.

7. The solar cell with a surface staged type antireflective layer according to claim 1, wherein the plurality of nanostructures are selected from any one of the structures of nano-protrusion structures, nano-hole structures and nano-line structures.

8. The solar cell with a surface staged type antireflective layer according to claim 7, wherein a method of forming the plurality of nanostructures is selected from any one of the methods of a metal assistance etching method, a dry etching method, a wet etching method, a photolithography etching method, a laser engraving method and a combination thereof.

9. The solar cell with a surface staged type antireflective layer according to claim 1, wherein the staged type antireflective layer further comprises a crystalline layer and a plurality of nano-column structures; the crystalline layer and the plurality of nano-column structures are sequentially formed on the plurality of nanostructures.

10. The solar cell with a surface staged type antireflective layer according to claim 9, wherein the crystalline layer is made of a material selected from any one of the materials of a zinc oxide and an aluminum-doped zinc oxide.

11. The solar cell with a surface staged type antireflective layer according to claim 10, wherein the crystalline layer can be formed by any one of the methods of an atomic layer deposition method, a spin-on coating method, a plasma enhanced chemical vapor deposition method, a molecular beam epitaxy method, a pulse laser deposition method, a radio frequency magnetron sputter method and a vapor liquid solid method.

12. The solar cell with a surface staged type antireflective layer according to claim 9, wherein the plurality of nano-column structures are made of a material of a zinc oxide.

13. The solar cell with a surface staged type antireflective layer according to claim 12, wherein the plurality of nano-column structures are formed by any one of the methods of a hydrothermal growth method, a sol-gel method, a metal organic chemical vapor deposition method, an electrochemical deposition method and a vapor transport deposition method.

14. The solar cell with a surface staged type antireflective layer according to claim 1, wherein a surface of the staged type antireflective layer is further coated with an antireflective coating layer.

15. The solar cell with a surface staged type antireflective layer according to claim 14, wherein the antireflective coating layer is made of a material selected from any one of the materials of a silicon nitride, titanium oxide and a combination thereof.

16. The solar cell with a surface staged type antireflective layer according to claim 15, wherein the antireflective coating layer is formed by any one of the methods of an atomic layer deposition method, a plasma enhanced chemical vapor deposition method, a molecular beam epitaxy method and a vapor liquid solid method.

17. The solar cell with a surface staged type antireflective layer according to claim 3, wherein the plurality of semiconductor layers can be any one of a Group IV element semiconductor and an alloy thereof, a compound semiconductor of Groups III-V, Groups II-VI and Groups IV-VI elements and an alloy thereof.

18. The solar cell with a surface staged type antireflective layer according to claim 4, wherein the plurality of semiconductor layers can be any one of a Group IV element semiconductor and an alloy thereof, a compound semiconductor of Groups III-V, Groups II-VI and Groups IV-VI elements and an alloy thereof.
